(19) United States
(12) Patent Application Publication
(10) Pub. No.: US 2014/0109402 A1
(43) Pub. Date: Apr. 24, 2014

(54) METHOD OF MANUFACTURING METAL CORE INSERTED PRINTED CIRCUIT BOARD

(71) Applicant: Samsung Electro-Mechanics Co., Ltd., Gyeonggi-do (KR)

(72) Inventor: Sang Hyuk Son, Gyeonggi-do (KR)

(73) Assignee: SAMSUNG ELECTRO-MECHANICS CO., LTD., Gyeonggi-do (KR)

(21) Appl. No.: 13/944,841

(22) Filed: Jul. 17, 2013

(30) Foreign Application Priority Data
Jul. 18, 2012 (KR) 10-2012-0078297

(51) Int. Cl. H05K 3/46

(52) U.S. Cl. CPC H05K 3/4644
USPC 29/830

(57) ABSTRACT

Disclosed herein is a method of manufacturing two PCBs through a single process by attaching a foam tape to each of a first copper clad laminate (CCL) and a second CCL including copper clad layers having differnet thicknesses, the method of manufacturing a metal core inserted PCB, the method including: preparing a first CCL and a second CCL including copper clad layers having different thicknesses; bonding the first CCL and the second CCL through a bonding member; forming grooves by etching an upper surface of th first CCL and a lower surface of the second CCL; and separating the first CCL and the second CCL from the bonding memebr at a previously set temperature as a first PCB and a second PCB having metal cores.

### CROSS REFERENCE(S) TO RELATED APPLICATIONS

This application claims the benefit under 35 U.S.C. Section 119 of Korean Patent Application Serial No. 10-2012-0078297, entitled “Method of Manufacturing Metal Core Inserted Printed Circuit Board (PCB)” filed on Jul. 18, 2012, which is hereby incorporated by reference in its entirety into this application.

### BACKGROUND OF THE INVENTION

1. Technical Field

The present invention relates to a method of manufacturing a metal core inserted printed circuit board (PCB), and more particularly, to a method of manufacturing two PCBs through a single process by attaching a foam tape to each of a first copper clad laminate (CCL) and a second CCL including copper clad layers having differnet thicknesses.

2. Description of the Related Art

A clock frequency of an AP chip increases in a recently releasing tablet PC or smart phone, and many functions are simultaneously used, and thus a malfunction of a reduction of lifetime of the AP chip due to heat are at issue. To solve these problems, a variety of methods of producing an effect of a heat dissipation, such as attaching a heat dissipation sheet and changing a material of a chassis, etc., have been introduced. Along with these methods, there are methods of increasing the effect of the heat dissipation by increasing an area in which heat is conducted by inserting a metal into a PCB, and accordingly minimizing loads applied to the AP chip.

However, the metal inserted into the PCB does not have a part supporting as epoxy, which does not make it easy to form a circuit. That is, when the metal is etched, since there is no supporting part in the lower portion of the metal, it is impossible to form a target, which needs to form a separate bridge. In this case, like a defect in which copper is exposed to the side occurs, a process of inserting a metal core into the PCB is not problematically easy. This will now be described below with reference to the drawing.

FIG. 1A to 1F are diagrams for explaining a conventional method of manufacturing a metal core inserted PCB.

Referring to FIG. 1A to 1F, a metal plate 1 is prepared. A dry film 2 is applied to upper and lower portions of the metal plate 1 and then exposed. After the dry film 2 is exposed, a groove is formed by etching, the dry film 2 is delaminated, prepregs 3 are filled in the groove and upper and lower surfaces of the metal plate 1, a copper clad layer 4 is finally stacked on upper and lower surfaces of the prepregs 3, and thus the metal core inserted PCB may be formed. However, such conventional technology needs a means for fixing the metal plate 1 in which the groove is formed in order to proceed with a subsequent process in a state where the groove is formed by etching.

In this case, a bridge is conventionally formed and thus an etching means except for the bridge is selected. This means problematically causes a defect due to exposure of copper. A detailed description thereof is omitted since this is a well-known technology.

Also, the etching means is conventionally selected after a carrier is formed in the lower portion of the metal plate 1 before etching. This means problematically causes complicated processing.

### RELATED ART DOCUMENT

### Patent Document

(Patent Document 1) Korean Patent Laid-Open Publication No. 10-2009-0028172

### SUMMARY OF THE INVENTION

An object of the present invention is to manufacture a printed circuit board (PCB) by up and down diagonally bonding clad metal laminates (CCLs) including copper clad layers having different thicknesses to upper and lower surfaces of a bonding member, thereby improving a defect in which exposure of copper is exposed by using a conventional bridge.

Another object of the present invention is to perform a process of manufacturing a PCB by up and down diagonally bonding CCLs to upper and lower surfaces of a bonding member, thereby preventing copper clad layer from warpage due to a structure of copper clad layers having different thicknesses.

Another object of the present invention is to perform a process of manufacturing two PCBs bonded to upper and lower surfaces of a boding member through a single process, and remove the bonding member at a final process, thereby increasing productivity by manufacturing two PCBs through a single process.

According to an exemplary embodiment of the present invention, there is provided a method of manufacturing a metal core inserted printed circuit board (PCB), the method including: preparing a first copper clad laminate (CCL) and a second CCL including copper clad layers having different thicknesses; bonding the first CCL and the second CCL to each other through a bonding member; forming grooves by etching an upper surface of the first CCL and a lower surface of the second CCL; and separating the first CCL and the second CCL from the bonding member at a previously set temperature as a first PCB and a second PCB having metal cores.

Each of the first CCL and the second CCL may incldue a first copper clad layer, a second copper clad layer, and an insualtion layer formed between the first copper clad layer and the second copper clad layer, whrein a thickness of the first copper clad layer is greater than that of the second copper clad layer.

The first copper clad layer may be a metal core layer of the separated PCB.

The second copper clad layer of the first CCL may be bonded to an upper surface of the bonding memebr, and the second copper clad layer of the second CCL may be bonded to a lower surface of the bonding member.

The method may further include, after the bonding, laminating dry films on the upper surface of the first CCL and the lower surface of the second CCL; and exposing the dry films.

The method may further include, after the forming of the grooves, delaminating the dry films by exposure; forming prepregs in the grooves, the upper surface of the first CCL, and the lower surface of the second CCL; and forming copper clad in the upper surface of the first CCL and the lower surface of the second CCL in which the prepregs are formed.

The method may further include, after the delaminating, forming roughness in the upper surface of the first CCL and the lower surface of the second CCL.

The insualtion layer and the prepregs may have the same components.

### BRIEF DESCRIPTION OF THE DRAWINGS

FIG. 1A to 1F are diagrams for describing a method of manufacturing a metal core inserted printed circuit board (PCB).

FIG. 2 is a diagram of copper clad laminates (CCLs) used in an embodiment of the present invention.

FIGS. 3 through 11 are diagrams for explaining a method of manufacturing a metal core inserted PCB according to an embodiment of the present invention.

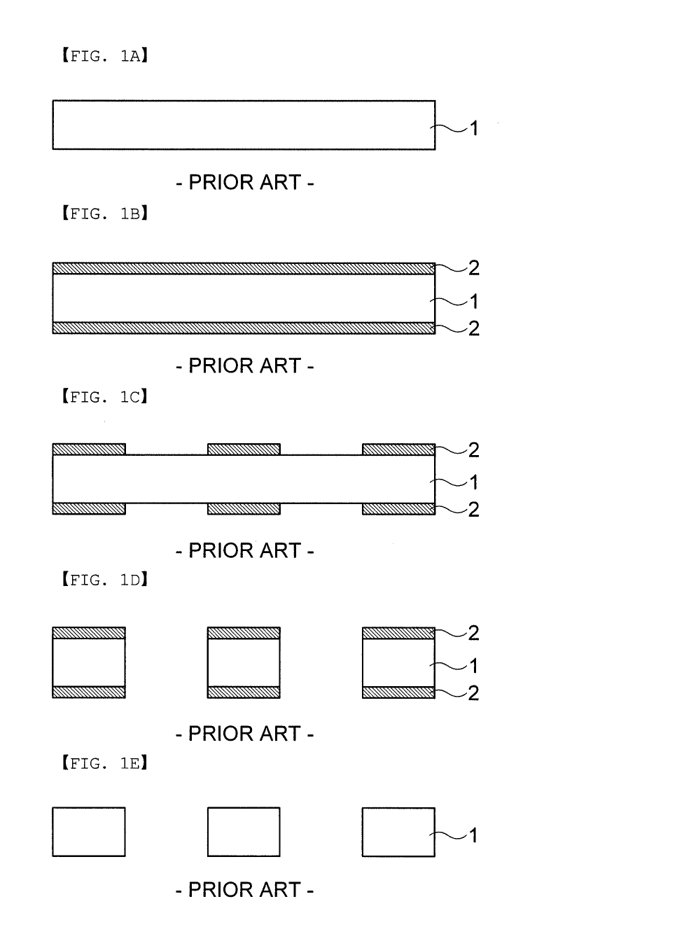

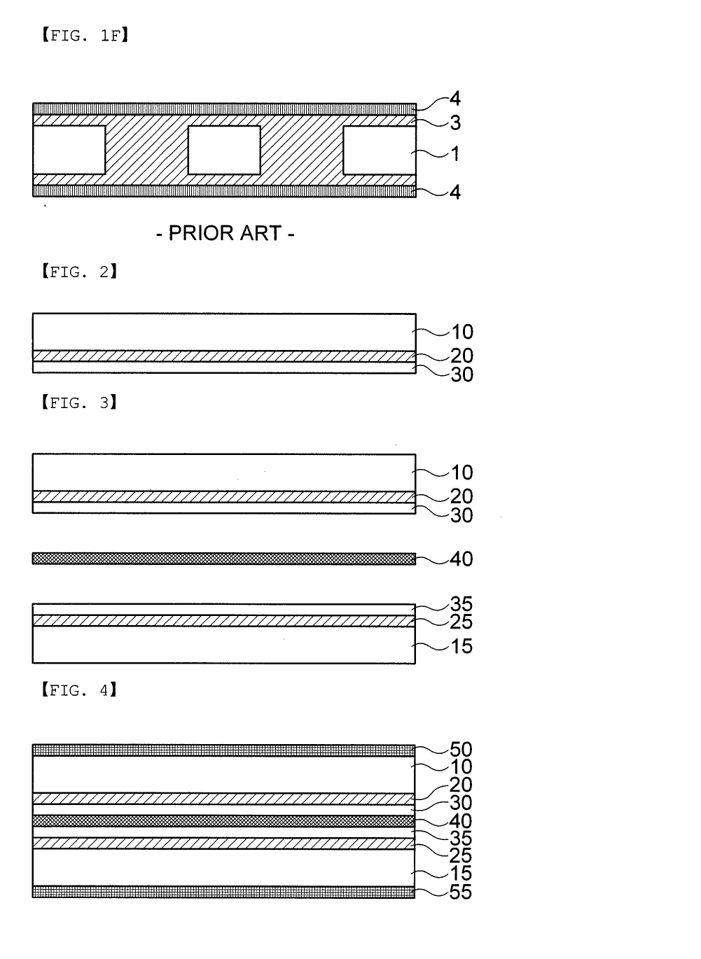

### DESCRIPTION OF THE PREFERRED EMBODIMENTS

Hereinafter, exemplary embodiments will be described in detail with reference to the accompanying drawings so that they can be easily practiced by those skilled in the art to which the present invention pertains.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

The embodiments of the present invention will now be described in detail with reference to accompanying drawings below.

FIG. 2 is a diagram of copper clad laminates (CCLs) having different thicknesses according to an embodiment of the present invention.

The CCLs having different thicknesses according to an embodiment of the present invention may include a first CCL and a second CCL. The first CCL may include an insulation layer 20, a first copper clad layer 10 formed on an upper portion of the insulation layer 20, and a second copper clad layer 30 formed on a lower portion of the insulation layer 20. In this case, a thickness of the first copper clad layer 10 may be greater than that of the second copper clad layer 30. Such structure applies to the second CCL.

FIG. 3 shows CCLs having different thicknesses stacked on upper and lower surfaces of a bonding member in a method of manufacturing a printed circuit board (PCB) according to an embodiment of the present invention.

Referring to FIG. 3, the method of manufacturing the PCB according to an embodiment of the present invention prepares a first CCL and a second CCL having different thicknesses and a bonding member 40. The first CCL and a second CCL may be configured as the CCLs having different thicknesses described with reference to FIG. I.

The first CCL may be stacked on an upper surface of the bonding member 40, and the second CCL may be stacked on a lower surface of the bonding member 40. A thickness of the second copper clad layer 30 of the first CCL contacting the bonding member 40 may be smaller than that of the first copper clad layer 10 of the first CCL. A thickness of a second copper clad layer 30 of the second CCL contacting the bonding member 40 may be smaller than that of a first copper clad layer 15 of the second CCL. Thus, the upper surface of the bonding member 40 is bonded to the second copper clad layer 30 of the first CCL, and the lower surface of the bonding member 40 is bonded to the second copper clad layer 35 of the second CCL. That is, the first CCL and the second CCL may be diagonally bonded to each other up and down with respect to the bonding member 40.

As such, since the first CCL and the second CCL have a non-diagonal structure including copper clad layers having different thicknesses, a warpage phenomenon may occur. The first CCL and the second CCL are diagonally bonded to each other up and down by the bonding member 40, which may prevent the warpage phenomenon. That is, the first CCL and the second CCL are diagonally bonded to the bonding member 40 up and down, and thus a warpage force of the first CCL and a warpage force of the second CCL are identical to each other and have opposite directions, thereby preventing the warpage phenomenon.

The bonding member 40 may be a foam tape. The foam tape is a tape having a bonding nature in both sides thereof, and loses a bonding force at a certain temperature, and thus bonding is naturally not made between the second copper clad layer 30 of the first CCL and the second copper clad layer 35 of the second CCL. That is, the bonding force of the foam tape is lost at a certain temperature, and thus the first CCL and the second CCL may be separated from each other.

In this case, a temperature at which the bonding force of the foam tape is lost may be 150° C. That is, the foam tape generates foam at a temperature higher than 150° C. and is hardened, which removes a bonding component from the foam tape, and thus the first CCL and the second CCL may be detached from the foam tape.

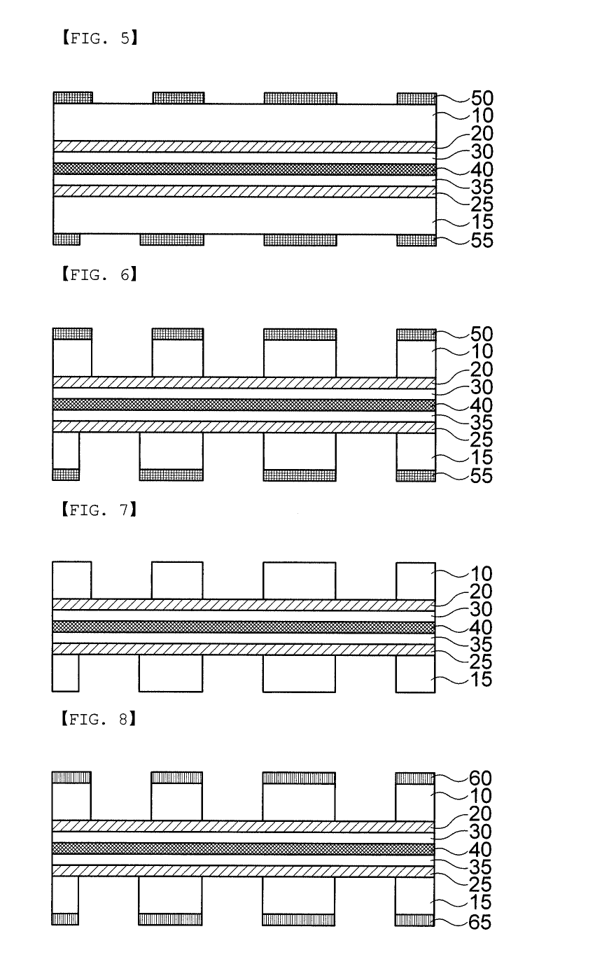

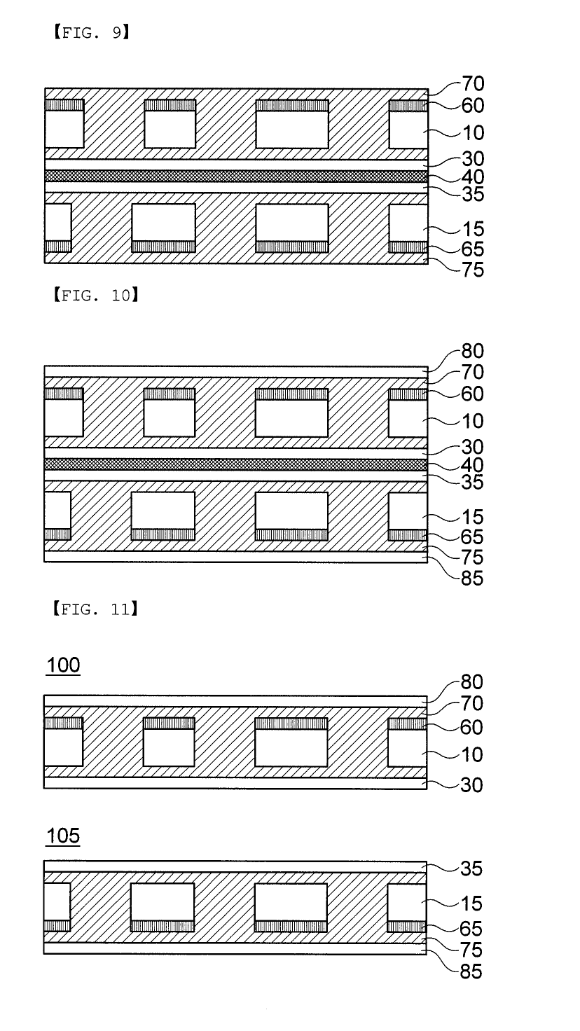

Referring to FIGS. 4 through 8, dry films 50 and 55 are applied to an upper surface of the first CCL and a lower surface of the second CCL and are exposed. After grooves are formed by etching, the dry films 50 and 55 are delaminated, and roughness 60 and 65 may be formed by a surface oxidation.

Referring to FIGS. 9 through 11, prepregs 70 and 75 are filled in the groove formed in the upper surface of the first CCL and the groove formed in the lower surface of the second CCL, and then copper clad layers 80 and 85 are stacked on the upper surface of the first CCL and the lower surface of the second CCL, respectively, and a certain temperature is applied thereto, and thus the first CCL and the second CCL may be separated as a first PCB 100 and a second PCB 105. Meanwhile, the prepregs 70 and 75 may be applied to the upper surface of the first CCL and the lower surface of the second CCL, respectively.

In this case, the prepregs 70 and 75 may be configured to have the same components as the insulation layers 20 and 25.

The first copper clad layer 10 of the first CCL may be a metal core layer of the first PCB 100. The first copper clad layer 15 of the second CCL may be a metal core layer of the second PCB 105. That is, the first copper clad layers 10 and 15 are the metal core layers, and thus heat generated in the board is dissipated to the outside, thereby producing an effect of heat dissipation.

As described above, a PCB is manufactured by up and down diagonally bonding CCLs including copper clad layers having different thicknesses to upper and lower surfaces of a bonding member, thereby improving a defect in which exposure of copper is exposed by using a conventional bridge.

Also, a process of manufacturing a PCB is performed by up and down diagonally bonding CCLs to upper and lower surfaces of a bonding member, thereby preventing copper clad layers from warpage due to a structure of copper clad layers having different thicknesses.

Furthermore, a process of manufacturing two PCBs bonded to upper and lower surfaces of a boding member is performed through a single process, and the bonding member is removed at a final process, thereby increasing productivity by manufacturing two PCBs through a single process.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A method of manufacturing a metal core inserted printed circuit board (PCB), the method comprising:
preparing a first copper clad laminate (CCL) and a second CCL including copper clad layers having different thicknesses;
bonding the first CCL and the second CCL to each other through a bonding member;
forming grooves by etching an upper surface of the first CCL and a lower surface of the second CCL; and
separating the first CCL and the second CCL from the bonding member at a previously set temperature as a first PCB and a second PCB having metal cores.

2. The method according to claim 1, wherein each of the first CCL and the second CCL includes a first copper clad layer, a second copper clad layer, and an insualtion layer formed between the first copper clad layer and the second copper clad layer,
whrein a thickness of the first copper clad layer is greater than that of the second copper clad layer.

3. The method according to claim 2, wherein the first copper clad layer is a metal core layer of the separated PCB.

4. The method according to claim 2, wherein the second copper clad layer of the first CCL is bonded to an upper surface of the bonding memebr, and the second copper clad layer of the second CCL is bonded to a lower surface of the bonding member.

5. The method according to claim 4, further comprising;, after the bonding,
laminating dry films on the upper surface of the first CCL and the lower surface of the second CCL; and
exposing the dry films.

6. The method according to claim 5, further comprising:, after the forming the grooves,
delaminating the dry films by exposure;
forming prepregs in the grooves, the upper surface of the first CCL, and the lower surface of the second CCL; and
forming copper clad in the upper surface of the first CCL and the lower surface of the second CCL in which the prepregs are formed.

7. The method according to claim 6, further comprising:, after the delaminating, forming roughness in the upper surface of the first CCL and the lower surface of the second CCL.

8. The method according to claim 6, wherein the insualtion layer and the prepregs have the same components.
